(19) United States
(12) Patent Application Publication
(10) Pub. No.: US 2011/0302858 A1
(43) Pub. Date: Dec. 15, 2011

(54) ROADS, WALLS, AND STRUCTURES FOR ENERGY GENERATION AND CONSERVATION

(76) Inventor: Bradley Duane Siewert, Placerville, CA (US)

(21) Appl. No.: 12/816,199

(22) Filed: Jun. 15, 2010

(51) Int. Cl. E04B 2/02; E01C 9/00; H02J 1/10; H01L 35/02; H01L 31/058

(52) U.S. Cl. 52/173.3; 136/206; 136/248; 307/25; 404/71; 257/E31.001

(57) ABSTRACT

A road, wall or structure for energy generation and conservation utilizing automated 3-Dimensional formless Nano, Micro and Macro-fabrication layering. Composition, material and geometric layouts dynamically changed over the volume of the part, based on 3-D CAD data. The applicator head applies successive layers to achieve the desired shape, geometry, strength, transparency, thickness, width, texture, porosity, electrical, magnetic and thermal properties base on the 3-D CAD data.

### BACKGROUND OF THE INVENTION

1. Field of the Invention

This invention relates to roads, walls and structures for energy generation and conservation using in general, 3 dimensional additive manufacturing techniques and processes to construct and integrate the energy harvesting and energy conservation techniques within or upon the volume of the road, wall or structure.

2. Description of the Background Art

Roads of various configurations and arrangements have been devised, based generally on a concrete or asphalt structure. Various mixes and or additives have been devised to reduce cost, extend life of material and or create longer or shorter handling times.

Roads, walls and structures cover trillions of square feet of the earth and with few exceptions generally do not use the volume of the material for energy generation.

With few exceptions, previously disclosed road, wall or structural systems rely on bulk layout processes and do not precisely layer structures with precision 3 dimensional attributes.

Accordingly, there is a need for a precision layered 3 dimensional road, wall or structural system. Where varying materials, conducting, semi-conducting, non-conducting, magnetic, metallic and non-metallic are integrated within or upon said superstructure to create energy generation, energy transmission, energy conservation, energy storage, levitation, propulsion, and structural support areas based on 3-D CAD design or data. The present invention satisfies these needs, as well as others, and generally overcomes the deficiencies found in the background art.

The foregoing reflects the state of the art of which the applicant is aware and is tendered with the view toward discharging applicant's acknowledged duty of candor in disclosing information which may be pertinent in the examination of this application. It is respectfully stipulated, however, that none of this information teaches or renders obvious applicant's claimed invention.

### SUMMARY OF THE INVENTION

The present invention takes advantage of the surface and space within the volume of the road, wall, or structure, which has heretofore not been utilized, by employing automated 3-dimensional formless nano, micro, macro-fabrication precision layering techniques for energy generation and conservation. The use of nano, micro, macro-materials, applications, techniques and designs employ the ability to integrate energy generation, energy conservation, energy storage, energy transmission, levitation, propulsion, induction, illumination, and structural reinforcements processes constructed within or upon road, wall, or structure.

Listed are a general representation of the abilities and do not encompass all energy generation, energy conservation, energy transmission, propulsion, levitation, illumination, or structural reinforcement techniques capable using the 3 Dimensional layering process:

(a) Photovoltaic power harvesting, harvesting solar energy;

(b) Piezoelectric power harvesting, converting vibration of vehicle moving upon road;

(c) Thermoelectric power harvesting, converting thermal gradients in the road structure;

(d) Electrodynamic or Electromagetic levitation

(e) RFID active and passive systems, sensors

(f) Linear induction or linear synchronous motors, propulsion

(g) Energy transmission from road way to vehicle, inductive power transfer

(h) Energy storage, Battery or capacitor storage integration

(i) Illumination, active and passive lighting integration

Further objects of the invention will be brought out in the following portions of the specification, wherein the detailed description is for the purpose of fully disclosing the invention without placing limits thereon.

### BREIF DESCRIPTION OF THE DRAWINGS

The invention will be more fully understood by reference to the following drawings, which are for illustrative purposes only.

FIG. 1 is a perspective view of a road in accordance with the present invention, showing a road way and a connection to utility power.

FIG. 2 is a cross-sectional view of the road system, showing a layout of integrated components.

FIG. 3 is a cross-sectional view of the road system, showing a layout of integrated components with void bridging techniques.

FIG. 4 is a perspective view of a wall system, showing a layout of integrated components

FIG. 5 is a perspective cross-sectional view of a bridge structure, showing integrated reinforcement components.

FIG. 6 is a cross-sectional view of the road system, showing a layout of integrated power storage devices, a photovoltaic energy harvesting layer, and reinforcing materials.

### DESCRIPTION OF THE PREFERRED EMBODIMENTS

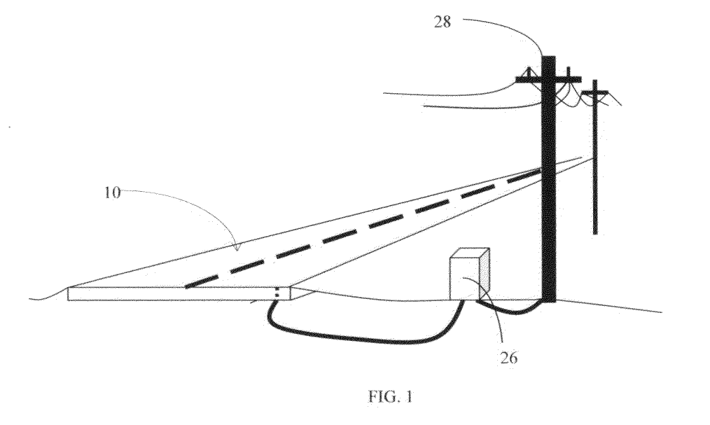

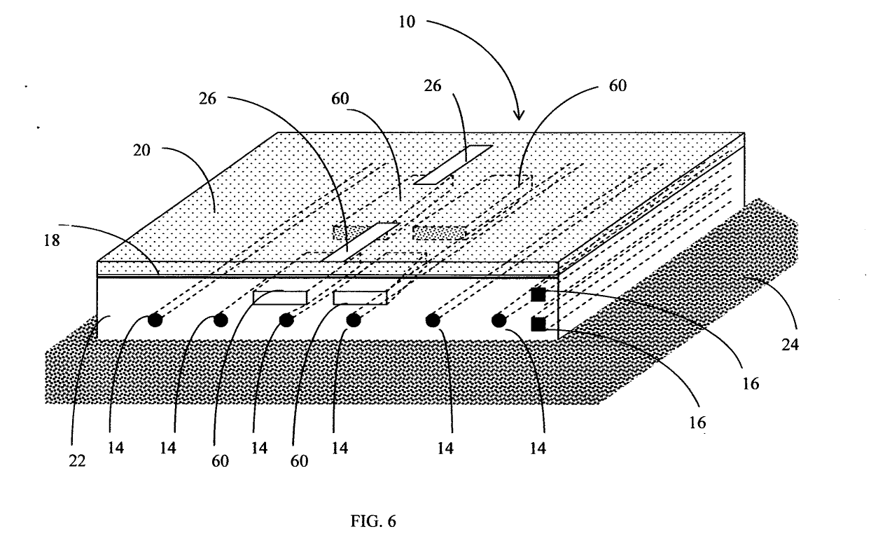

Referring more specifically to the drawings, for illustrative purposes the present invention is embodied in the road, wall and bridge systems, which is generally shown in FIG. 1 through FIG. 6, where the reference numerals denote like parts. It will be appreciated by persons of ordinary skill in the art that the road, wall, or structure comprising the present invention may vary as to configuration and as to details without departing from the basic concepts as disclosed herein.

Referring to FIGS. 1,2, 3, and 6, there is shown an embodiment of the energy generation and energy conservation road system 10 comprising the present invention.

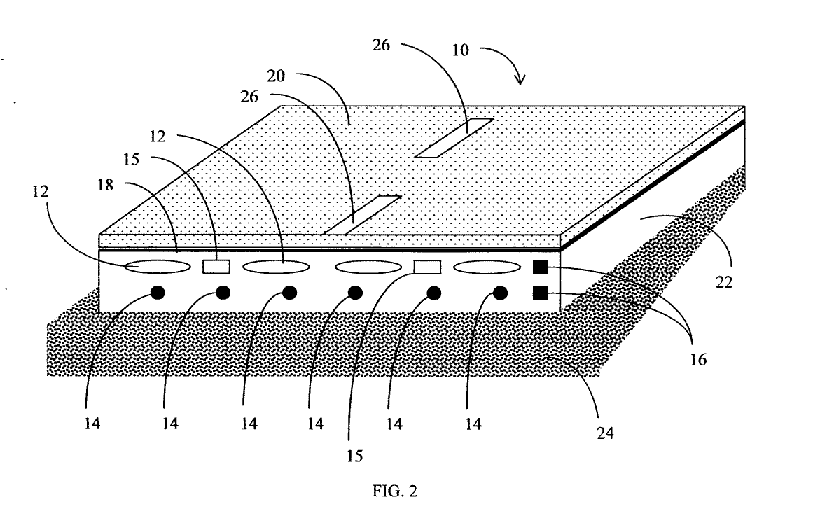

FIG. 2 is a cross-sectional perspective view of the road system, showing a plurality of Halbach arrays 12, precisely fabricated within the ceramic road structure 22, reinforcement members 14, power conducting rails 16, photovoltaic energy harvesting layer 18, and transparent wear surface 20 fabricated atop existing road and power conditioner system 26, allowing power generation from road to be feed in to utility power grid 28. Induction feed rail 15, transfers power to vehicles using utility feed or store energy 60, in roadway. Road illumination 26, using passive or active illumination techniques are shown integrated in to surface layers of road.

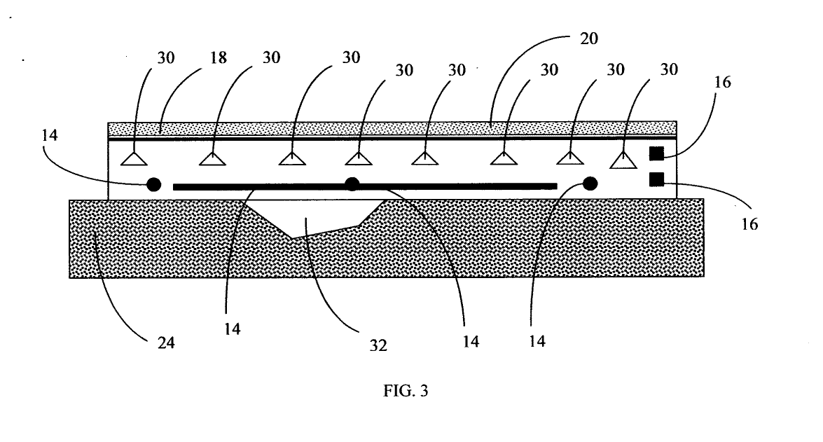

FIG. 3 is a cross-sectional view of the road system in FIG. 2 showing hallow sections 30 designed within ceramic road structure to reduce material or use as integrated conduits. Configuration is based on road designers engineered 3-D CAD data. The automated 3-dimensional formless nano, micro, macro-fabrication layering head recognizes unsupported areas 32, in base gravel 24, and fuses the road, wall or structures material at the needed angle to bridge the void 32. Energy generated from energy harvesting techniques within or upon road embodiment feeds power conducting rails 16, supplying the integrated fabricated batteries 60, and or capacitors 60 within road or a power conditioning and collection unit 26. Reinforcement materials 14, are shown in a longitudinal and latitudinal format to properly support span. Reinforcement material 14, can be integrated in any size, shape, cross-section or geometric layout.

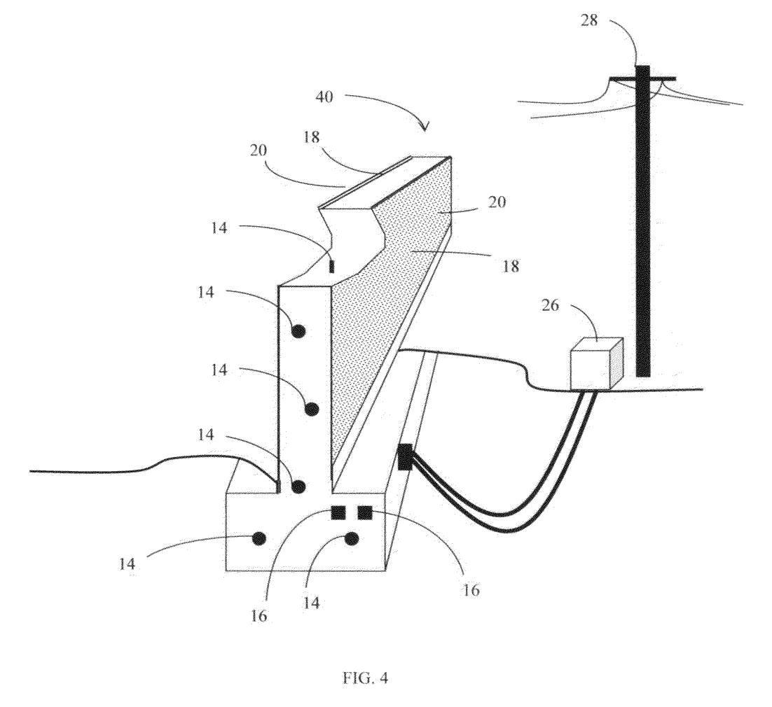

FIG. 4 is a perspective view of a wall system 40, showing a photovoltaic energy harvesting layer 18, integrated in the vertical surface of wall, beneath a transparent ware surface 20. Reinforcement materials 14, are shown in a vertical and horizontal directions. Power conducting rails 16, in substructure are feeding power conditioning and collection unit 26, before feeding utility power grid 28.

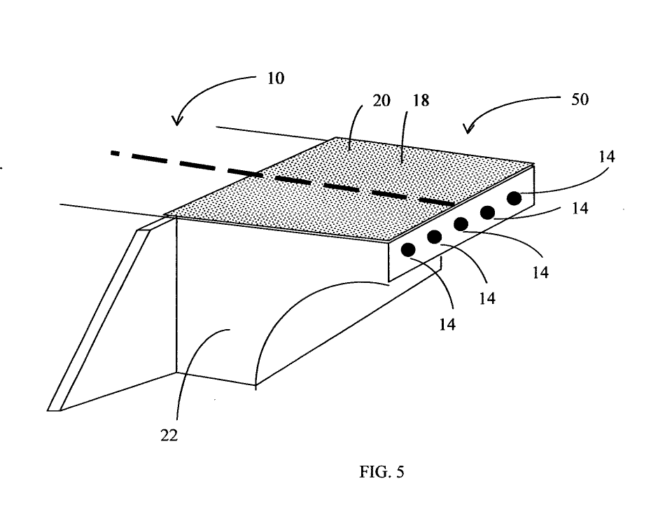

FIG. 5 is a perspective cross-sectional view of a simple bridge structure 50, showing reinforcement components 14, integrated in to structure as the 3-dimensional formless nano, micro, macro-fabrication layers are applied to create this structure. Photovoltaic energy harvesting layer 18, is applied below the transparent ware surface 20.

What is claimed is:

1) Roadway, wall or structure comprising:
(a) Three dimensional precise layering of nano, micro and macro materials for energy generation, energy conservation, energy storage, energy transmission, levitation, propulsion, induction, illumination and structural reinforcements processes.
(b) Precisely places material(s) based on 3 Dimensional CAD design or data.

2) Three dimensional system as recited in claim 1, laser deposition process fuses non-conducting and conducting materials creating rigid superstructures.

3) Three dimensional system as recited in claim 1, application of electrically conducting, super-conducting, semi-conducting and or non-conducting materials to form integrated substructures within and or upon said superstructure.

4) Three dimensional system as recited in claim 1, application of thermally conducting and or thermally resistant materials to form integrated substructures within and or upon said superstructure.

5) Three dimensional system as recited in claim 1, application of magnetic materials to form integrated substructures within and or upon said superstructure.

6) Three dimensional system as recited in claim 1, application of materials to form integrated reinforcement members or areas within or upon said superstructure.

7) Three dimensional system as recited in claim 1, atomic alignment of layered materials placed precisely using physical placement, electrostatic, magnetic, electromagnetic, light, and chemical/biological self-assembly.

8) Three dimensional system as recited in claim 1, employees laser peening or laser shock peening to components increasing strength based on 3D CAD data.

9) Three dimensional system as recited in claim 1, creation of hallow areas within superstructure to allow the creation of conduits, culverts or structural voids.

10) Three dimensional system as recited in claim 1, application of energy storage materials within said superstructure.

11) Three dimensional system as recited in claim 1, Appling MICRO, NANO, META, and MEM materials, process and techniques.
